(19) United States
(12) Patent Application Publication
(10) Pub. No.: US 2026/0311762 A1
(43) Pub. Date: Oct. 8, 2026

(54) MEMORY APPARATUS

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/457,180

(22) Filed: Jan. 23, 2026

(30) Foreign Application Priority Data
Apr. 2, 2025 (TW) 114112727

(51) Int. Cl. G11C 16/08; G11C 16/04

(52) U.S. Cl. CPC G11C 16/08; G11C 16/0483

(57) ABSTRACT

A memory apparatus is provided. A first selection circuit selectively connects a first global word line decoder to a part of multiple first global word lines according to a selected even memory block. A second selection circuit transmits a first global word line selection signal to the selected even memory block according to the selected even memory block. A third selection circuit selectively connects a second global word line decoder to a part of multiple second global word lines according to a selected odd memory block. A fourth selection circuit transmits a second global word line selection signal to the selected odd memory block according to the selected odd memory block.

### CROSS-REFERENCE TO RELATED APPLICATION

This application claims the priority benefit of Taiwan application serial no. 114112727, filed on Apr. 2, 2025. The entirety of the above-mentioned patent application is hereby incorporated by reference herein and made a part of this specification.

### BACKGROUND

### Technical Field

The disclosure relates to an electronic device, and more particularly to a memory apparatus.

### Description of Related Art

With the rapid development of semiconductor technology, the capacity of the memory is increasing, and the length of word lines in the memory cell array is also becoming longer. However, long word lines lead to high capacitance loads, and the driving current needs to be increased accordingly, causing the area of the charge pump circuit to be increased, and the current consumption is also increased, which is not conducive to energy saving and carbon reduction.

### SUMMARY

The disclosure provides a memory apparatus, which can effectively reduce a high capacitance load caused by a long word line to prevent increasing an area and current consumption of a charge pump circuit.

A memory apparatus of the disclosure includes a memory cell array, an even row decoder circuit, and an odd row decoder circuit. The memory cell array includes multiple even memory blocks and multiple odd memory blocks. The even row decoder circuit is coupled to the memory cell array, and the even row decoder circuit includes a first global word line decoder, a first selection circuit, and a second selection circuit. The first global word line decoder provides multiple first global word line selection signals. The first selection circuit is coupled to the first global word line decoder and multiple first global word lines, and selectively connects the first global word line decoder to a part of the first global word lines according to the selected even memory block. The second selection circuit is coupled to the first global word lines and the even memory blocks, and transmits the first global word line selection signals to the selected even memory block according to the selected even memory block. The odd row decoder circuit is coupled to the memory cell array, and the odd row decoder circuit includes a second global word line decoder, a second selection circuit, and a third selection circuit. The second global word line decoder provides multiple second global word line selection signals. The third selection circuit is coupled to the second global word line decoder and multiple second global word lines, and selectively connects the second global word line decoder to a part of the second global word lines according to the selected odd memory block. A fourth selection circuit is coupled to the second global word lines and the odd memory blocks, and transmits the second global word line selection signals to the selected odd memory block according to the selected odd memory block.

In an embodiment of the disclosure, the memory apparatus is a NAND memory apparatus. Based on the above, according to the embodiment of the disclosure, the first selection circuit selectively connects the first global word line decoder to a part of the first global word lines according to the selected even memory block, the second selection circuit transmits the first global word line selection signal to the selected even memory block according to the selected even memory block, the third selection circuit selectively connects the second global word line decoder to a part of the second global word lines according to the selected odd memory block, and the fourth selection circuit transmits the second global word line selection signal to the selected odd memory block according to the selected odd memory block. In this way, the global word line decoder is selectively connected to a part of the global word lines by the selection circuit according to the selected memory block, which may shorten the length of the global word line, and reduce the number of word line decoders connected to the global word line decoder, so as to effectively prevent increasing the area and the current consumption of the charge pump circuit.

### BRIEF DESCRIPTION OF THE DRAWINGS

FIGS. 1 and 2 are schematic diagrams of a memory apparatus according to an embodiment of the disclosure.

FIG. 3 is a schematic diagram of a transmission circuit according to an embodiment of the disclosure.

FIGS. 4 and 5 are schematic diagrams of a memory apparatus according to another embodiment of the disclosure.

### DESCRIPTION OF THE EMBODIMENTS

In order for the content of the disclosure to be more comprehensible, the following specific embodiments are given as examples according to which the disclosure can indeed be implemented. In addition, wherever possible, elements/components/steps using the same reference numerals in the drawings and the implementations represent the same or similar parts.

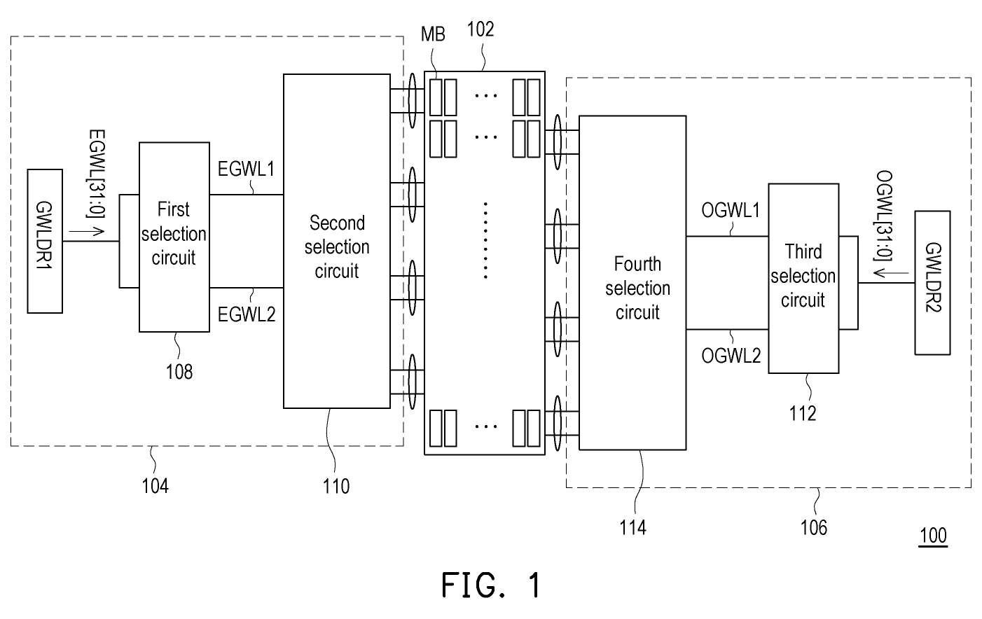

Please refer to FIG. 1 hereinafter. FIG. 1 is a schematic diagram of a memory apparatus according to an embodiment of the disclosure. A memory apparatus 100 may be, for example, a NAND memory apparatus and includes a memory cell array 102, an even row decoder circuit 104, and an odd row decoder circuit 106. The memory cell array 102 is coupled to the even row decoder circuit 104 and the odd row decoder circuit 106. The memory cell array 102 may include multiple memory blocks MB, and the memory blocks MB may include, for example, NAND strings. The even row decoder circuit 104 may decode a row address, and select a corresponding even memory block among the memory blocks MB for reading or writing of data. Similarly, the odd row decoder circuit 106 may decode a row address, and select a corresponding odd memory block among the memory blocks MB for reading or writing of data.

Further, in the embodiment of FIG. 1, the memory cell array 102 may include, for example, 2048 memory blocks MB. The even row decoder circuit 104 may include, as shown in FIG. 1, a first global word line decoder GWLDR1, a first selection circuit 108, and a second selection circuit 110. The first selection circuit 108 is coupled to the first global word line decoder GWLDR1 and is coupled to the second selection circuit 110 through first global word lines EGWL1 and EGWL2. The second selection circuit 110 is also coupled to the even memory block in the memory cell array 102. The first global word line EGWL1 may be, for example, used to couple 512 even memory blocks among the 1024 even memory blocks, and the first global word line EGWL2 may be used to couple the remaining 512 even memory blocks among the 1024 even memory blocks. The first global word line decoder GWLDR1 may be coupled to a part of the even memory blocks in the memory cell array 102 through the first selection circuit 108, the first global word line EGWL1, and the second selection circuit 110, and may be coupled to another part of the even memory blocks in the memory cell array 102 through the first selection circuit 108, the first global word line EGWL2, and the second selection circuit 110.

Similarly, the odd row decoder circuit 106 may include a second global word line decoder GWLDR2, a third selection circuit 112, and a fourth selection circuit 114. The second selection circuit 110 is coupled to the second global word line decoder GWLDR2 and is coupled to the fourth selection circuit 114 through second global word lines OGWL1 and OGWL2. The fourth selection circuit 114 is also coupled to the odd memory block in the memory cell array 102. The second global word line OGWL1 may be, for example, used to couple 512 odd memory blocks among the 1024 odd memory blocks, and the second global word line OGWL2 may be used to couple the remaining 512 odd memory blocks among the 1024 odd memory blocks. The second global word line decoder GWLDR2 may be coupled to a part of the odd memory blocks in the memory cell array 102 through the third selection circuit 112, the second global word line OGWL1, and the fourth selection circuit 114, and may be coupled to another part of the odd memory blocks in the memory cell array 102 through the third selection circuit 112, the second global word line OGWL2, and the fourth selection circuit 114.

The first selection circuit 108 may selectively connect the first global word line decoder GWLDR1 to the first global word line corresponding to the selected even memory block according to the selected even memory block, so as to transmit a first global word line selection signal EGWL[31:0] to the selected even memory block. For example, in the embodiment of FIG. 1, if the selected even memory block corresponds to the first global word line EGWL1, the first selection circuit 108 may selectively connect the first global word line decoder GWLDR1 to the first global word line EGWL1 according to the selected even memory block, and the second selection circuit 110 transmits the first global word line selection signal EGWL[31:0] from the first global word line EGWL1 to the selected even memory block according to the selected even memory block.

Similarly, the third selection circuit 112 may selectively connect a second global word line decoder GWLDR2 to the second global word line corresponding to the selected odd memory block according to the selected odd memory block, so as to transmit a second global word line selection signal OGWL[31:0] to the selected odd memory block. For example, if the selected odd memory block corresponds to the second global word line OGWL1, the third selection circuit 112 may selectively connect the second global word line decoder GWLDR2 to the second global word line OGWL1 according to the selected odd memory block, and the fourth selection circuit 114 transmits the second global word line selection signal OGWL[31:0] from the second global word line OGWL1 to the selected odd memory block according to the selected odd memory block.

In this way, the first global word line decoder GWLDR1 is selectively connected to a part of the first global word lines (for example, as shown in the above embodiment, the first global word line decoder GWLDR1 is selectively connected to the first global word line EGWL1 corresponding to the selected even memory block, but not connected to the first global word line EGWL2), which may effectively shorten the length of the first global word line and reduce the number of circuit elements connected to the first global word line decoder GWLDR1 (for example, the number of unselected word line decoders) when driving the selected even memory block. In addition, the number of memory blocks connected to the first global word line decoder GWLDR1 may also be reduced, thereby significantly reducing the capacitance load of the global word line to effectively prevent increasing an area and current consumption of a charge pump circuit used to drive the even row decoder circuit 104. Similarly, the second global word line decoder GWLDR2 is selectively connected to a part of the second global word lines, which may also effectively prevent increasing the area and the current consumption of the charge pump circuit used to drive the odd row decoder circuit 106.

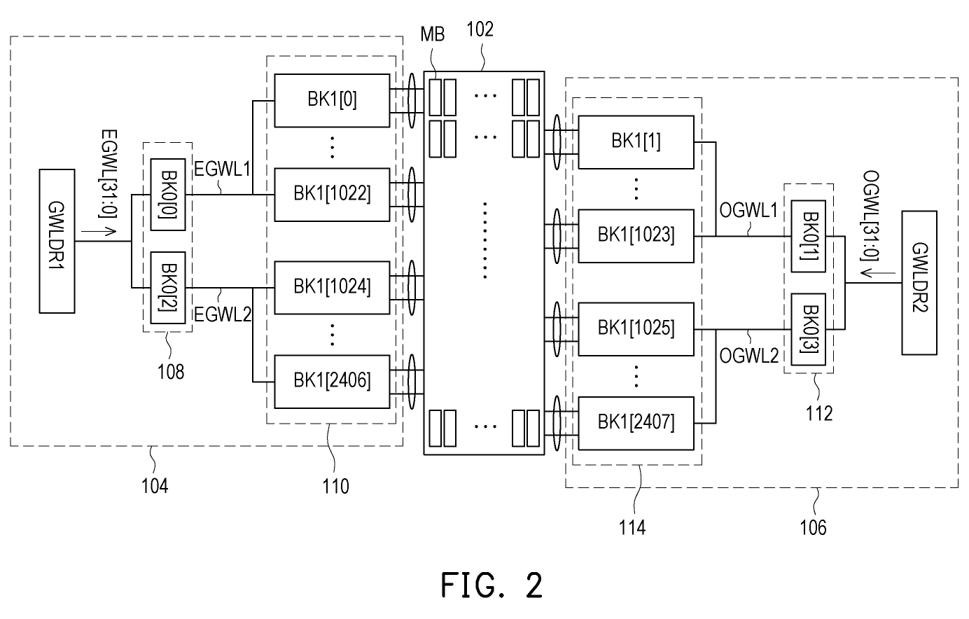

Furthermore, the first selection circuit 108, the second selection circuit 110, the third selection circuit 112, and the fourth selection circuit 114 may be, for example, respectively implemented by multiple transmission circuits. For example, as shown in FIG. 2, the first selection circuit 108 may include 2 first transmission circuits BK0[0] and BK0[2], the second selection circuit 110 may include 1024 second transmission circuits BK1[0] to BK1[2046], the third selection circuit 112 may include 2 fourth transmission circuits BK0[1] and BK0[3], and the fourth selection circuit 114 may include 1024 fifth transmission circuits BK1[1] to BK1[2047]. The first transmission circuit BK0[0] is coupled to the first global word line decoder GWLDR1 and the corresponding first global word line EGWL1, the first transmission circuit BK0[2] is coupled to the first global word line decoder GWLDR1 and the corresponding first global word line EGWL2, the second transmission circuits BK1[0] to BK1[1022] are respectively coupled between the corresponding first transmission circuit BK0[0] and the corresponding even memory block, and the second transmission circuits BK1[1024] to BK1[1046] are respectively coupled between the corresponding first transmission circuit BK0[2] and the corresponding even memory block.

Similarly, the fourth transmission circuit BK0[1] is coupled to the second global word line decoder GWLDR2 and the corresponding second global word line OGWL1, the fourth transmission circuit BK0[3] is coupled to the second global word line decoder GWLDR2 and the corresponding second global word line OGWL2, the fifth transmission circuits BK1[1] to BK1[1023] are respectively coupled between the corresponding fourth transmission circuit BK0[1] and the corresponding odd memory block, and the fifth transmission circuits BK1[1025]to BK1[2047] are respectively coupled between the corresponding fourth transmission circuit BK0[3] and the corresponding even memory block.

The first transmission circuits BK0[0] and BK0[2] may transmit the first global word line selection signal EGWL[31:0] to a part of the first global word lines (for example, the first global word line EGWL1 or EGWL2) according to the selected even memory block. The second transmission circuits BK1[0] to BK1[2046]may transmit the first global word line selection signal EGWL[31:0] to the selected even memory block according to the selected even memory block. The third transmission circuits BK0[1] and BK0[3] may transmit the second global word line selection signal OGWL[31:0] to a part of the second global word lines (for example, the second global word line OGWL1 or OGWL2) according to the selected odd memory block. The fourth transmission circuits BK1[1] to BK1[2047] may transmit the second global word line selection signal OGWL[31:0] to the selected odd memory block according to the selected odd memory block.

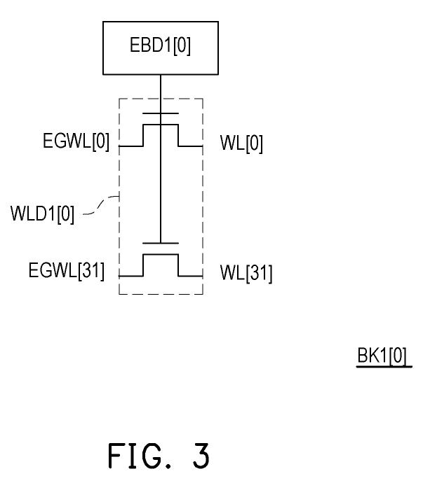

Specifically, the first transmission circuits BK0[0] and BK0[2], the second transmission circuits BK1[0] to BK1[2046], the fourth transmission circuits BK0[1] and BK0[3], and the fifth transmission circuits BK1[1] to BK1[2047] may respectively include a block decoder and a word line decoder, wherein the word line decoder may include multiple transistors. For example, as shown in FIG. 3, taking the second transmission circuit BK1[0] as an example, the second transmission circuit BK1[0] includes a block decoder EBD1[0] and a word line decoder WLD1[0]. The word line decoder WLD1[0] includes 32 transistors, each transistor is coupled between a corresponding first global word line and a corresponding local word line, and a control terminal of each transistor is coupled to the block decoder EBD1[0]. In the case where the second transmission circuit BK1[0] is coupled to the selected even memory block, each transistor may be controlled by the block decoder EBD1[0] to provide first global word line selection signals EGWL[0] to EGWL[31] as local word line selection signals WL[0] to WL[31] to the selected even memory block. In the case where the second transmission circuit BK1[0] is coupled to the unselected even memory block, each transistor is controlled by the block decoder EBD1[0] and is in a disconnected state.

Similarly, taking the first transmission circuit BK0[0] as an example, each transistor in the first transmission circuit BK0[0] is coupled between the first global word line decoder GWLDR1 and the corresponding first global word line EGWL1, and the conduction state of each transistor is controlled by the corresponding block decoder. In the case where the first transmission circuit BK0[0] is coupled to the selected even memory block, each transistor may be controlled by the corresponding block decoder to transmit the first global word line selection signal EGWL[31:0] to the first global word line EGWL1. In the case where the first transmission circuit BK0[0] is coupled to the unselected even memory block, each transistor is controlled by the corresponding block decoder and is in a disconnected state. The implementations of the first transmission circuit BK0[2] and the fourth transmission circuits BK0[1] and BK0[3] are similar to that of the first transmission circuit BK0[0], and the implementations of the second transmission circuits BK1[2] to BK1[2046] and the fifth transmission circuits BK1[1] to BK1[2047] are similar to that of the second transmission circuit BK1[0], which are not described in detail here.

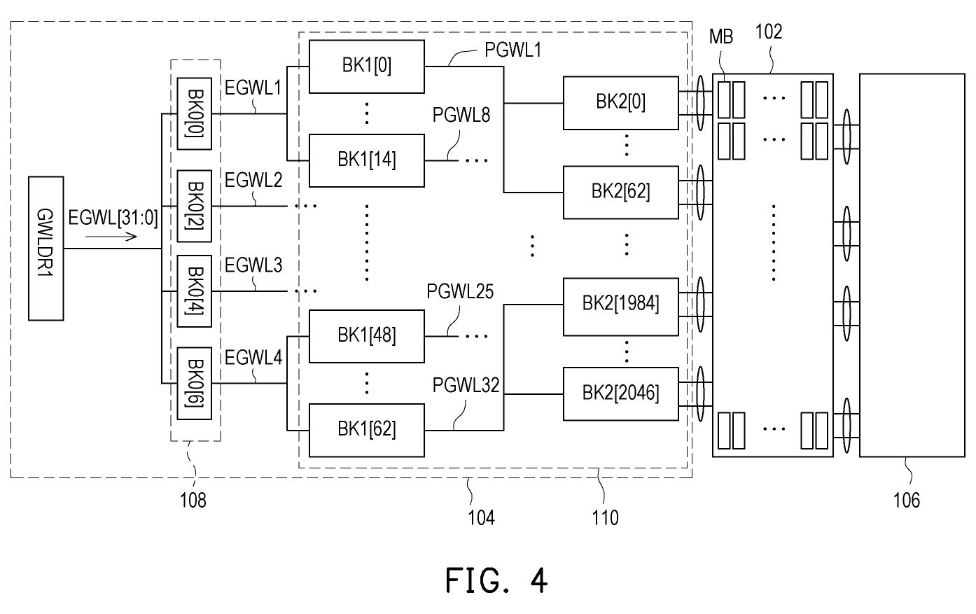

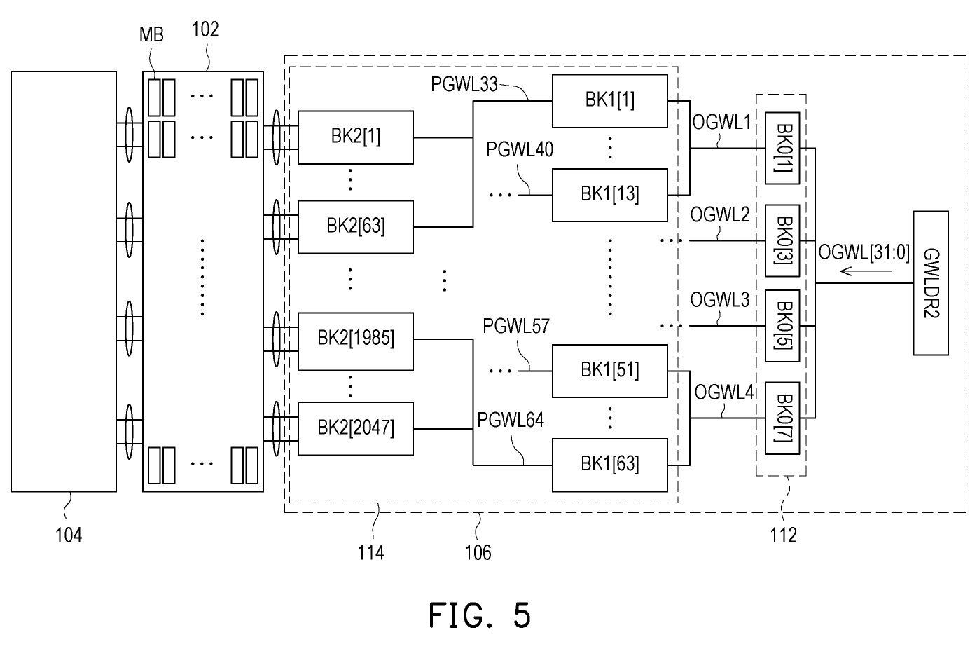

It should be noted that in other embodiments, the first selection circuit 108, the second selection circuit 110, the third selection circuit 112, and the fourth selection circuit 114 may include more transmission circuits and are not limited to the above embodiment. As shown in FIGS. 4 and 5 (to ensure the readability of the drawings, the implementation details of the even row decoder circuit 104 and the odd row decoder circuit 106 are respectively illustrated in FIGS. 4 and 5), and the first selection circuit 108 may include 4 first transmission circuits BK0[0] to BK0[6], and the second selection circuit 110 may include 32 second transmission circuits BK1[0] to BK1[62] and 1024 third transmission circuits BK2[0] to BK2[2046], wherein each first transmission circuit is coupled to 8 corresponding second transmission circuits, and each second transmission circuit is coupled to 32 corresponding third transmission circuits. For example, the first transmission circuit BK0[0] is coupled to the second transmission circuits BK1[0] to BK1[14], the first transmission circuit BK0[2] is coupled to the second transmission circuits BK1[16] to BK1[30], ..., and the first transmission circuit BK0[6] is coupled to the second transmission circuits BK1[48] to BK1[62]. The second transmission circuit BK1[0] is coupled to the third transmission circuits BK2[0] to BK2[62], the second transmission circuit BK1[2] is coupled to the third transmission circuits BK2[64] to BK2[126], ..., and so on.

The first transmission circuits BK0[0] to BK0[6], the second transmission circuits BK1[0] to BK1[62], and the third transmission circuits BK2[0] to BK2[2046] of the embodiment may also be implemented in the manner of the embodiment of FIG. 3. In the embodiment, the transistors in the first transmission circuits BK0[0] to BK0[6] are coupled between the first global word line decoder GWLDR1 and corresponding first global word lines EGWL1 to EGWL4, the transistors in the second transmission circuits BK1[0] to BK1[62]are coupled between the corresponding first global word lines EGWL1 to EGWL4 and corresponding third global word lines PGWL1 to PGWL32, and the transistors in the third transmission circuits BK2[0] to BK2[2046] are coupled between the corresponding third global word lines PGWL1 to PGWL32 and the corresponding even memory block.

Similar to the embodiment of FIG. 2, the first transmission circuits BK0[0] to BK0[6] may transmit the first global word line selection signal EGWL[31:0] to a part of the first global word lines (for example, one of the first global word lines EGWL1 to EGWL4) according to the selected even memory block. The second transmission circuits BK1[0] to BK1[31] may transmit the first global word line selection signal EGWL[31:0] to a part of the third global word lines (for example, one of the third global word lines PGWL1 to PGWL32) according to the selected even memory block. The third transmission circuits BK2[0] to BK2[1023] may transmit the first global word line selection signal EGWL[31:0] to the selected even memory block according to the selected even memory block.

For example, if the selected even memory block is coupled to the third transmission circuit BK2[0], since the third transmission circuit BK2[0] is coupled to the second transmission circuit BK1[0] through the third global word line PGWL1, and the second transmission circuit BK1[0] is coupled to the first global word line decoder GWLDR1 through the first global word line EGWL1, the selected even memory block corresponds to the first global word line EGWL1 and the third global word line PGWL1. The first transmission circuit BK0[0] may transmit the first global word line selection signal EGWL[31:0] to the first global word line EGWL1 according to the selected even memory block. The second transmission circuit BK1[0] may transmit the first global word line selection signal EGWL[31:0] to the third global word line PGWL1 according to the selected even memory block. The third transmission circuit BK2[0] transmits the first global word line selection signal EGWL[31:0] to the selected even memory block. While the third transmission circuit BK2[0] transmits the first global word line selection signal EGWL[31:0] to the selected even memory block, the third transmission circuits BK2[2] to BK2[2046], the second transmission circuits BK1[2] to BK1[62], and the first transmission circuits BK0[2] to BK0[6] are in a state of being unable to transmit the first global word line selection signal EGWL[31:0], that is, the transistors in the third transmission circuits BK2[2] to BK2[2046], the second transmission circuits BK1[2] to BK1[62], and the first transmission circuits BK0[2] to BK0[6] are in a disconnected state.

Compared to the embodiment of FIG. 2, the embodiment further reduces the number of circuit elements connected to the first global word line decoder GWLDR1 (the number of unselected word line decoders) when driving the selected even memory block to further reduce the capacitance load of the global word line, so as to reduce the area and the current consumption of the charge pump circuit used to drive the even row decoder circuit 104.

Similarly, the implementations of the third selection circuit 112 and the fourth selection circuit 114 may be as shown in FIG. 5. The third selection circuit 112 and the fourth selection circuit 114 may be connected through the second global word lines OGWL1 to OGWL4. The third selection circuit 112 may include 4 fourth transmission circuits BK0[1] to BK0[7]. The fourth selection circuit 114 may include 32 fifth transmission circuits BK1[1] to BK1[63] and 1024 sixth transmission circuits BK2[1] to BK2[2047]. The fifth transmission circuits BK1[1] to BK1[63] and the sixth transmission circuits BK2[1] to BK2[2047] may be connected through fourth global word lines PGWL33 to PGWL64. Since the odd row decoder circuit 106 and the even row decoder circuit 104 have symmetrical circuit structures, a person skilled in the art should be able to infer the detailed implementation of the odd row decoder circuit 106 from the above embodiment, which will not be described in detail here.

It should be noted that in other embodiments, the number of transmission circuits in the first selection circuit 108, the second selection circuit 110, the third selection circuit 112, and the fourth selection circuit 114 is not limited to the above embodiment. Through increasing the number of transmission circuits in the first selection circuit 108, the second selection circuit 110, the third selection circuit 112, and the fourth selection circuit 114 in the manner of the above embodiment to reduce the number of circuit elements connected to the first global word line decoder GWLDR1 when driving the selected even memory block, the capacitance load of the global word line may be effectively and significantly reduced, so as to reduce the area and the current consumption of the charge pump circuit used to drive the even row decoder circuit 104.

It should be further noted that to simplify the drawings, in the examples of FIGS. 1, 2, 4, and 5, only 1 of each of the first global word lines EGWL1 to EGWL4, the second global word lines OGWL1 to OGWL4, the third global word lines PGWL1 to PGWL32, and the fourth global word lines PGWL33 to PGWL64 is drawn as a representative. In fact, in the examples of FIGS. 1, 2, 4, and 5, the numbers of the first global word lines EGWL1 to EGWL4, the second global word lines OGWL1 to OGWL4, the third global word lines PGWL1 to PGWL32, and the fourth global word lines PGWL33 to PGWL64 are all 32. In other embodiments, the number of each of the first global word lines EGWL1 to EGWL4, the second global word lines OGWL1 to OGWL4, the third global word lines PGWL1 to PGWL32, and the fourth global word lines PGWL33 to PGWL64 is the same as the number of local word lines in one memory block.

In summary, according to the embodiment of the disclosure, the first selection circuit selectively connects the first global word line decoder to a part of the first global word lines according to the selected even memory block, the second selection circuit transmits the first global word line selection signal to the selected even memory block according to the selected even memory block, the third selection circuit selectively connects the second global word line decoder to a part of the second global word lines according to the selected odd memory block, and the fourth selection circuit transmits the second global word line selection signal to the selected odd memory block according to the selected odd memory block. In this way, the length of the global word line may be shortened, and the number of word line decoders connected to the global word line decoder may be reduced, so as to effectively prevent increasing the area and the current consumption of the charge pump circuit.

What is claimed is:

1. A memory apparatus, comprising:
a memory cell array, comprising a plurality of even memory blocks and a plurality of odd memory blocks;
an even row decoder circuit, coupled to the memory cell array, the even row decoder circuit comprising:
a first global word line decoder, providing a plurality of first global word line selection signals;
a first selection circuit, coupled to the first global word line decoder and a plurality of first global word lines, and selectively connecting the first global word line decoder to a part of the first global word lines according to the selected even memory block; and
a second selection circuit, coupled to the first global word lines and the even memory blocks, and transmitting the first global word line selection signals to the selected even memory block according to the selected even memory block; and
an odd row decoder circuit, coupled to the memory cell array, the odd row decoder circuit comprising:
a second global word line decoder, providing a plurality of second global word line selection signals;
a third selection circuit, coupled to the second global word line decoder and a plurality of second global word lines, and selectively connecting the second global word line decoder to a part of the second global word lines according to the selected odd memory block; and
a fourth selection circuit, coupled to the second global word lines and the odd memory blocks, and transmitting the second global word line selection signals to the selected odd memory block according to the selected odd memory block.

2. The memory apparatus according to claim 1, wherein the first selection circuit comprises:
a plurality of first transmission circuits, respectively coupled to the first global word line decoder and the corresponding first global word line, and transmitting the first global word line selection signals to the part of the first global word lines according to the selected even memory block.

3. The memory apparatus according to claim 2, wherein the second selection circuit comprises:
a plurality of second transmission circuits, respectively coupled between the corresponding first transmission circuit and the corresponding even memory block, and transmitting the first global word line selection signals according to the selected even memory block to transmit the first global word line selection signals to the selected even memory block.

4. The memory apparatus according to claim 3, wherein the second selection circuit further comprises:
a plurality of third transmission circuits, respectively coupled between the corresponding second transmission circuit and the corresponding even memory block, and transmitting the first global word line selection signals according to the selected even memory block to transmit the first global word line selection signals to the selected even memory block.

5. The memory apparatus according to claim 2, wherein each of the first transmission circuits, each of the second transmission circuits, and each of the third transmission circuits respectively comprises:
a block decoder; and
a first word line decoder, controlled by the block decoder to transmit the first global word line selection signals to transmit the first global word line selection signals to the selected even memory block.

6. The memory apparatus according claim 3, wherein each of the first transmission circuits, each of the second transmission circuits, and each of the third transmission circuits respectively comprises:
a block decoder; and
a first word line decoder, controlled by the block decoder to transmit the first global word line selection signals to transmit the first global word line selection signals to the selected even memory block.

7. The memory apparatus according to claim 4, wherein each of the first transmission circuits, each of the second transmission circuits, and each of the third transmission circuits respectively comprises:
a block decoder; and
a first word line decoder, controlled by the block decoder to transmit the first global word line selection signals to transmit the first global word line selection signals to the selected even memory block.

8. The memory apparatus according to claim 5, wherein the first word line decoder comprises:
a plurality of first transistors, wherein control terminals of the first transistors are coupled to the even block decoder, and conduction states of the first transistors are controlled by the even block decoder to transmit the first global word line selection signals.

9. The memory apparatus according to claim 6, wherein the first word line decoder comprises:
a plurality of first transistors, wherein control terminals of the first transistors are coupled to the even block decoder, and conduction states of the first transistors are controlled by the even block decoder to transmit the first global word line selection signals.

10. The memory apparatus according to claim 7, wherein the first word line decoder comprises:
a plurality of first transistors, wherein control terminals of the first transistors are coupled to the even block decoder, and conduction states of the first transistors are controlled by the even block decoder to transmit the first global word line selection signals.

11. The memory apparatus according to claim 1, wherein the third selection circuit comprises:
a plurality of fourth transmission circuits, respectively coupled to the second global word line decoder and the corresponding second global word line, and transmitting the second global word line selection signals to the part of the second global word lines according to the selected odd memory block.

12. The memory apparatus according to claim 11, wherein the fourth selection circuit comprises:
a plurality of fifth transmission circuits, respectively coupled between the corresponding fourth transmission circuit and the corresponding odd memory block, and transmitting the second global word line selection signals according to the selected odd memory block to transmit the second global word line selection signals to the selected odd memory block.

13. The memory apparatus according to claim 12, wherein the second selection circuit comprises:
a plurality of sixth transmission circuits, respectively coupled between the corresponding fifth transmission circuit and the corresponding odd memory block, and transmitting the second global word line selection signals according to the selected odd memory block to transmit the second global word line selection signals to the selected odd memory block.

14. The memory apparatus according to claim 11, wherein each of the fourth transmission circuits, each of the fifth transmission circuits, and each of the sixth transmission circuits respectively comprises:
a block decoder; and
a second word line decoder, controlled by the odd block decoder to transmit the second global word line selection signals to transmit the second global word line selection signals to the selected odd memory block.

15. The memory apparatus according to claim 12, wherein each of the fourth transmission circuits, each of the fifth transmission circuits, and each of the sixth transmission circuits respectively comprises:
a block decoder; and
a second word line decoder, controlled by the odd block decoder to transmit the second global word line selection signals to transmit the second global word line selection signals to the selected odd memory block.

16. The memory apparatus according to claim 13, wherein each of the fourth transmission circuits, each of the fifth transmission circuits, and each of the sixth transmission circuits respectively comprises:
a block decoder; and
a second word line decoder, controlled by the odd block decoder to transmit the second global word line selection signals to transmit the second global word line selection signals to the selected odd memory block.

17. The memory apparatus according to claim 14, wherein the second word line decoder comprises:
a plurality of second transistors, wherein control terminals of the second transistors are coupled to the odd block decoder, and conduction states of the second transistors are controlled by the odd block decoder to transmit the second global word line selection signals.

18. The memory apparatus according to claim 15, wherein the second word line decoder comprises:
a plurality of second transistors, wherein control terminals of the second transistors are coupled to the odd block decoder, and conduction states of the second transistors are controlled by the odd block decoder to transmit the second global word line selection signals.

19. The memory apparatus according to claim 16, wherein the second word line decoder comprises:
a plurality of second transistors, wherein control terminals of the second transistors are coupled to the odd block decoder, and conduction states of the second transistors are controlled by the odd block decoder to transmit the second global word line selection signals.

20. The memory apparatus according to claim 1, wherein the memory apparatus is a NAND memory apparatus.
